(19) United States
(12) Patent Application Publication
(10) Pub. No.: US 2022/0376006 A1
(43) Pub. Date: Nov. 24, 2022

(54) DISPLAY PANEL AND DISPLAY APPARATUS

(71) Applicant: BOE TECHNOLOGY GROUP CO., LTD., Beijing (CN)

(72) Inventors: Shipei LI, Beijing (CN); Ying ZHAO, Beijing (CN); Yang YUE, Beijing (CN); Xuefei ZHAO, Beijing (CN); Wei HE, Beijing (CN); Wusheng LI, Beijing (CN); Qi YAO, Beijing (CN)

(21) Appl. No.: 17/765,035

(22) PCT Filed: May 20, 2021
(86) PCT No.: PCT/CN2021/094845

§ 371 Date: Mar. 30, 2022

(30) Foreign Application Priority Data
Jun. 9, 2020 (CN) 202010519444.1

(51) Int. Cl. H01L 27/32; H01L 51/52

(52) U.S. Cl. CPC H01L 27/3227; H01L 51/5275; H01L 51/5237; H01L 27/3246; H01L 27/322

(57) ABSTRACT

A display panel includes a substrate and a plurality of photosensitive elements on the substrate, wherein at least a portion of the photosensitive elements are provided with corresponding light-adjusting structures; the light-adjusting structure is on a side of the photosensitive element away from the substrate, and is configured to adjust a propagation direction of incident light reflected by a print and incident on the light-adjusting structure, and to output formed emergent light to the photosensitive element corresponding to the light-adjusting structure, and an included angle between the propagation direction of the formed emergent light and the plane, where the substrate is located, is greater than an included angle between the propagation direction of the incident light and the plane where the substrate is located; and the photosensitive element is configured to generate a corresponding electrical signal according to the received light, to identify an image of the print.

### TECHNICAL FIELD

The present disclosure relates to the field of display technology, and in particular, to a display panel and a display apparatus.

### BACKGROUND

In order to reduce a thickness of a product, some manufacturers have proposed a technical solution of integrating an optical fingerprint recognition sensor (a photosensitive element, such as a PIN photodiode) inside a display panel in an embedded (In-Cell) manner. Specifically, a display element (for example, an organic light emitting diode) for picture display and a photosensitive element for fingerprint identification are manufactured in a display panel, respectively. The photosensitive element receives light reflected by a valley or a ridge of a fingerprint, and generates a corresponding electrical signal. Since the reflected light by the valley and the reflected light by the ridge are different from each other, the generated electrical signals are also different, and thus the valley and the ridge can be recognized.

However, in practical applications, it is found that both the amount of light reflected by the valley of the fingerprint and reaching the photosensitive element and the amount of light reflected by the ridge of the fingerprint and reaching the photosensitive element are less, so that the difference between the electrical signals generated by the photosensitive element corresponding to the valley of the fingerprint and the photosensitive element corresponding to the ridge of the fingerprint is less, which affects the final recognition accuracy.

### SUMMARY

The present disclosure is directed to at least one of the technical problems of the prior art, and provides a display panel and a display apparatus.

In a first aspect, an embodiment of the present disclosure provides a display panel, including: a substrate and a plurality of photosensitive elements on the substrate, wherein at least a part of the plurality of photosensitive elements each are provided with a light-adjusting structure;

the light-adjusting structure is on a side of the photosensitive element away from the substrate, and is configured to adjust a propagation direction of incident light reflected by a print and incident on the light-adjusting structure, and to output formed emergent light to the photosensitive element corresponding to the light-adjusting structure, and an included angle between a propagation direction of the formed emergent light and a plane, where the substrate is located, is greater than an included angle between the propagation direction of the incident light and the plane where the substrate is located; and the photosensitive element is configured to generate a corresponding electrical signal according to received light, to identify an image of the print.

In some embodiments, the light-adjusting structure has a light-incident surface and a light-emergent surface, the light-incident surface is on a side of the light-adjusting structure away from the substrate, and the light-emergent surface is on a side of the light-adjusting structure close to the substrate; and in the display panel, a refractive index of a film layer in contact with the light-incident surface of the light-adjusting structure is less than that of the light-adjusting structure, and a refractive index of a film layer in contact with the light-emergent surface of the light-adjusting structure is greater than that of the light-adjusting structure.

In some embodiments, the light-adjusting structure has a triangular prism shape, and the light-adjusting structure in the triangular prism shape has a triangular cross-sectional shape in a cross section perpendicular to a plane where the substrate is located; or the light-adjusting structure has a plano-convex lens shape, and a planar surface of the light-adjusting structure in the plano-convex lens shape is close to the substrate.

In some embodiments, an orthographic projection of the photosensitive element on the substrate is within an area defined by an orthographic projection of the corresponding photosensitive element on the substrate.

In some embodiments, the display panel further includes:

an encapsulation layer on a side of the plurality of photosensitive elements away from the substrate; and

a protective layer on a side of the encapsulation layer away from the substrate, wherein the light-adjusting structure is between the protective layer and the encapsulation layer.

In some embodiments, wherein each of the plurality of photosensitive elements includes a first electrode, a photosensitive pattern on a side of the first electrode away from the substrate, and a second electrode on a side of the photosensitive pattern away from the substrate; and

the display panel further includes:

a cover layer on a side of the plurality of photosensitive elements away from the substrate; and

a signal transmission trace on a side of the cover layer away from the substrate, and connected to the second electrode of the photosensitive element through a via.

In some embodiments, the signal transmission trace includes a first portion in an area where the photosensitive element is located, and a second portion outside the area where the photosensitive element is located;

the first portion is connected to the second electrode through a via, and includes a first transparent conductive pattern; and

the second portion includes a second transparent conductive pattern, a first metal conductive pattern and a third transparent conductive pattern, which are stacked in a direction away from the substrate, and the second transparent conductive pattern and the first transparent conductive pattern are in a same layer and are connected to each other.

In some embodiments, the display panel further includes a pixel defining layer and a plurality of display elements;

wherein the pixel defining layer is on a side of the plurality of photosensitive elements away from the substrate, and is provided with a plurality of pixel accommodating openings, which correspond to the plurality of display elements in a one-to-one correspondence; and

each of the plurality of display elements is in a corresponding one of the plurality of pixel accommodating openings, and an orthographic projection of the plurality of display elements on the substrate does not overlap an orthographic projection of the plurality of photosensitive elements on the substrate.

In some embodiments, the display panel further includes:

a thin film transistor array on a side of the plurality of photosensitive elements close to the substrate, and including a plurality of thin film transistors, wherein each of the plurality of thin film transistors corresponds to and electrically connected to one of plurality of photosensitive elements or one of the plurality of display elements.

In some embodiments, a material of the pixel defining layer includes a color filter material having a transmission wavelength ranging from 380 nm to 600 nm and an absorption wavelength greater than 600 nm.

In some embodiments, the display panel further includes:

a planarization layer between the plurality of photosensitive elements and the pixel defining layer.

In a second aspect, an embodiment of the present disclosure further provides a display apparatus, including the display panel as provided in the above first aspect.

### BRIEF DESCRIPTION OF DRAWINGS

FIG. 1 is a schematic diagram illustrating a principle of performing fingerprint recognition in a display panel involved in the related art;

FIG. 2 is a schematic cross-sectional view of a partial area of a display panel according to an embodiment of the disclosure;

FIG. 3 is a schematic diagram illustrating an optical path for fingerprint recognition using a photosensitive element according to an embodiment of the present disclosure;

FIG. 4a is a schematic diagram illustrating a structure of a light-adjusting structure according to an embodiment of the present disclosure;

FIG. 4b is a schematic cross-sectional view of the light-adjusting structure taken along a direction A-A′ in FIG. 4a;

FIG. 5a is a schematic diagram illustrating a structure of a light-adjusting structure according to an embodiment of the present disclosure;

FIG. 5b is a schematic cross-sectional view of the light-adjusting structure taken along a direction A-A′ of FIG. 5a;

FIG. 6 is a schematic diagram illustrating an arrangement of display elements and photosensitive elements according to an embodiment of the present disclosure;

FIG. 7 is a flowchart of a method for manufacturing a display panel according to an embodiment of the disclosure;

FIG. 8 is a flowchart of a method for manufacturing a display panel according to an embodiment of the present disclosure; and

FIGS. 9A to 9N are schematic cross-sectional views of intermediate products for manufacturing a display panel with the manufacturing method shown in FIG. 8.

### DETAIL DESCRIPTION OF EMBODIMENTS

In order to enable one of ordinary skill in the art to better understand the technical solutions of the present disclosure, a display panel, a manufacturing method thereof, and a display apparatus according to the embodiment of the present disclosure are described in detail below with reference to the accompanying drawings.

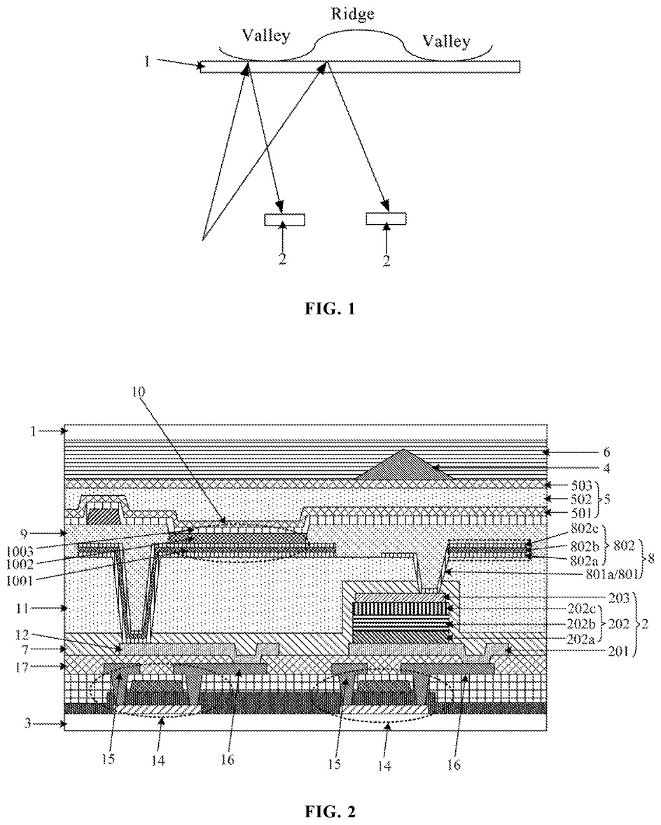

FIG. 1 is a schematic diagram illustrating a principle of performing fingerprint recognition in a display panel involved in the related art. As shown in FIG. 1, a point light source is present in the display panel, light emitted by the point light source in all directions independently propagates without interfering with each other, and some of the light emitted by the point light source may reach a cover plate 1. When the cover plate 1 is pressed by a fingerprint, ridges of the fingerprint are in contact with the surface of the cover plate 1, and air is present between valleys of the fingerprint and the cover plate 1.

When the light irradiates the cover plate 1 at a position which is in contact with the ridge of the fingerprint, due to a small difference between refractive indices of the finger and the cover plate 1, most of the light reaching the position is transmitted at the interface between the ridge of the fingerprint and the cover plate 1, and a small portion of the light is reflected. When light irradiates the position, which is directly opposite to the valley of the fingerprint, on the cover plate 1, due to the air between the valley of the fingerprint and the cover plate 1, and a large difference between the refractive indices of the air and the cover plate 1 (the air is an optically thinner medium, and the cover plate 1 is an optically denser medium), most of the light reaching the position is reflected at the interface between the air and the cover plate 1, and a small portion of the light is transmitted. That is, the amount of light reflected by the cover plate 1 at the position corresponding to the valley of the fingerprint is greater than the amount of light reflected by the cover plate 1 at the position corresponding to the ridge of the fingerprint.

The reflected light is directed to the photosensitive element 2 at a corresponding position, and the photosensitive element 2 generates a corresponding electrical signal according to the received light. Specifically, a current of the electrical signal generated by the photosensitive element 2 corresponding to the valley of the fingerprint is greater than a current of the electrical signal generated by the photosensitive element 2 corresponding to the ridge of the fingerprint.

However, in practical applications, it is found that, when the light reflected by the surface of the cover plate 1 is directed to the photosensitive element 2, most of the reflected light will be reflected at an interface of film layers between the photosensitive element 2 and the cover plate 1, and finally, the amount of light that can be transmitted to the photosensitive element is small, so that the difference between the electrical signals generated by the photosensitive element 2 corresponding to the valley of the fingerprint and the photosensitive element 2 corresponding to the ridge of the fingerprint is small, which is not favorable for identification of the ridge and the valley of the fingerprint.

To solve the technical problem, an embodiment of the present disclosure provides a corresponding solution, which will be described in detail below with reference to the accompanying drawings.

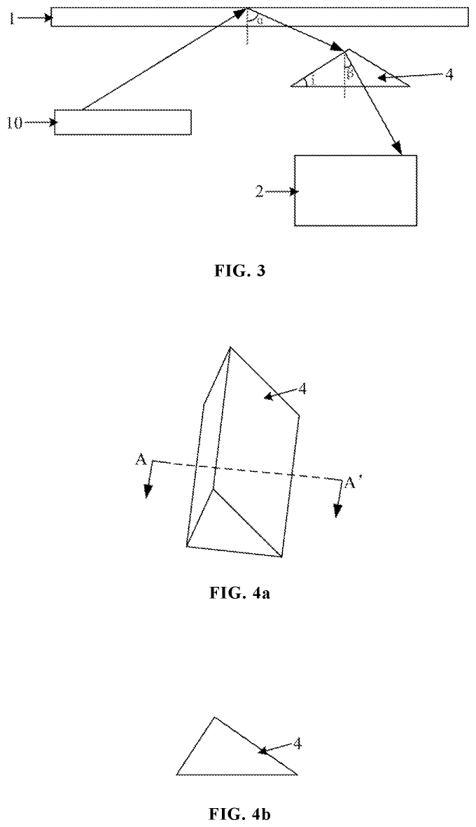

FIG. 2 is a schematic cross-sectional view of a partial area of a display panel according to an embodiment of the disclosure. As shown in FIG. 2, the display panel includes a substrate 3 and a plurality of photosensitive elements 2 located on the substrate 3, at least a part of the plurality of photosensitive elements 2 are configured with corresponding light-adjusting structures 4. The light-adjusting structure 4 is located on a side of the photosensitive element 2 away from the substrate 3, is configured to adjust a propagation direction of incident light reflected by a print and incident on the light-adjusting structure 4, and then output formed emergent light to the photosensitive element 2 corresponding to the light-adjusting structure 4, and an included angle between the propagation direction of the emergent light and the plane, where the substrate 3 is located, is greater than an included angle between the propagation direction of the incident light and the plane where the substrate 3 is located. The photosensitive element 2 is configured to generate a corresponding electrical signal according to received light.

It should be noted that the “print” in the embodiments of the present disclosure includes, but are not limited to, a fingerprint or a palm print.

In addition, in practical applications, the propagation directions of all incident light reflected by the print and incident on the light-adjusting structure 4 at a same moment are not completely the same (the propagation directions of an entire light beam formed by all incident light are scattered); according to an embodiment of the present disclosure, an included angle between a propagation direction of the emergent light and a plane, where the substrate 3 is located, is greater than an included angle between a propagation direction of the incident light and a plane where the substrate 3 is located, which specifically means that, for an incident light, the propagation direction of which is constant, the light-adjusting structure may adjust the propagation direction of the incident light, and make an included angle between the propagation direction of the emergent light, which is formed after the incident light is adjusted, and the plane, where the substrate 3 is located, greater. For the entire light beam incident on the light-adjusting structure 4, a divergence angle of an entire light beam of the emergent light is less than that of an entire light beam of the incident light.

In some embodiments, the display panel further includes a plurality of display elements 10 for performing a picture display, and there is no overlap between an orthographic projection of the display elements 10 on the substrate 3 and an orthographic projection of the photosensitive element 2 on the substrate 3.

In some embodiments, an outermost side of the display panel is provided with a cover plate 1 for an overall encapsulation and protection of the display panel.

In an embodiment of the present disclosure, the display element 10 is an Organic Light-Emitting Diode (OLED), and the photosensitive element 2 is a PIN photodiode. In addition, FIG. 1 only illustrates one display element 10, one photosensitive element 2 and one light-adjusting structure 4, which does not limit the technical solution of the present disclosure.

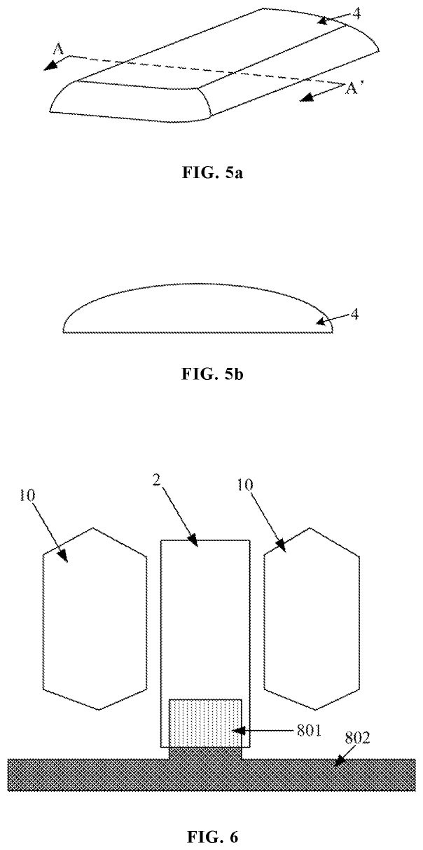

FIG. 3 is a schematic diagram of an optical path for fingerprint identification using a photosensitive element according to an embodiment of the present disclosure. As shown in FIG. 3, according to an embodiment of the present disclosure, when fingerprint identification is performed, the display element 10 for displaying a picture is multiplexed into a point light source. When the light emitted from the point light source is irradiated onto the cover plate 1, a portion of the light is transmitted and emitted out of the display panel, and the other portion of the light is reflected, and the reflected light is directed to the substrate 3.

When the reflected light reaches a light-incident surface of the light-adjusting structure 4, the reflected light enters the light-adjusting structure 4 as an incident light to be subjected to light-adjusting of the light-adjusting structure 4, and then is output by the light-adjusting structure 4 as an emergent light. An included angle between the propagation direction of the emergent light and the plane, where the substrate 3 is located, is greater than an included angle between the propagation direction of the incident light and the plane, where the substrate 3 is located.

For convenience of description, a term “reference line” is introduced as a virtual line, which is perpendicular to the plane where the substrate 3 is located. The included angle between the incident light and the reference line is recorded as α, the included angle between the emergent light and the reference line is recorded as β, and β is less than α.

In the embodiment of the present disclosure, by providing the light-adjusting structure 4, the incident angle formed between the emergent light and the interface between every two adjacent film layers can be reduced, when the emergent light is directed to the photosensitive element 2. According to Fresnel reflection principle, when the intensity of the incident light is constant and the light enters an interface between two media having different refractive indices, the smaller the incident angle is, the smaller the intensity of the reflected light and the greater the intensity of the refracted light are. That is, in the case of a constant amount of incident light, the smaller the incident angle is, the smaller the amount of light reflected at the interface between two adjacent film layers and the larger the amount of light transmitted through the interface between the two adjacent film layers are. Therefore, compared with the technical solutions in the related art, the technical solution according to the embodiment of the present disclosure can reduce the amount of light reflected at the interface between the film layers when the light is directed to the photosensitive element 2, so that the amount of light finally reaching the photosensitive element 2 is increased. Accordingly, the difference between the electrical signals generated by the photosensitive elements 2 corresponding to the valley and the ridge of the fingerprint is increased (the magnitudes of two currents of the electrical signals are obviously different from each other), which is beneficial to improving the fingerprint identification accuracy.

In some embodiments, the light-adjusting structure 4 has a light-incident surface and a light-emergent surface, the light-incident surface is located on a side of the light-adjusting structure 4 away from the substrate 3, and the light-emergent surface is located on a side of the light-adjusting structure 4 facing the substrate 3. In the display panel, the refractive index of a film layer in contact with the light-incident surface of the light-adjusting structure 4 is less than the refractive index of the light-adjusting structure 4, and the refractive index of a film layer in contact with the light-emergent surface of the light-adjusting structure 4 is greater than the refractive index of the light-adjusting structure 4. The design, that the refractive index of the film layer in contact with the light-incident surface of the light-adjusting structure 4 is less than the refractive index of the light-adjusting structure 4, is to refract the incident light when the incident light enters the light-adjusting structure 4 through the light-incident surface, and to make an included angle between the refracted light and the reference line be less than an included angle between the incident light and the reference line. The design, that the refractive index of the film layer in contact with the light-emergent surface of the light-adjusting structure 4 is greater than the refractive index of the light-adjusting structure 4, is to reduce the amount of light reflected at the light-emergent surface and increase the amount of the emergent light exiting from the light-emergent surface.

It should be noted that the refractive index of the film layer in contact with the light-incident surface of the light-adjusting structure 4 is less than the refractive index of the light-adjusting structure 4, and the refractive index of the film layer in contact with the light-emergent surface of the light-adjusting structure 4 is greater than the refractive index of the light-adjusting structure 4, and this design is only a preferred embodiment of the present disclosure, to increase the light intensity of the emergent light as much as possible, but this design does not limit the technical solution of the present disclosure.

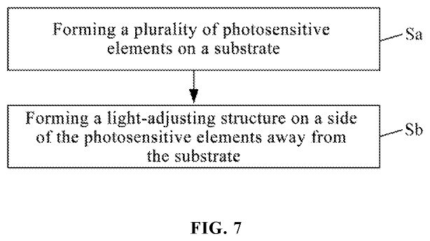

FIG. 4a is a schematic diagram illustrating a structure of a light-adjusting structure according to an embodiment of the present disclosure, and FIG. 4b is a schematic cross-sectional view taken along a direction A-A′ in FIG. 4a. As shown in FIGS. 4a and 4b, as an alternative embodiment, the light-adjusting structure 4 is shaped as a triangular prism, and a cross section of the light-adjusting structure 4 in the triangular prism shape, perpendicular to the plane where the substrate 3 is located, has a triangular cross-sectional shape.

At least one side surface of the triangular prism may be used as a light-incident surface, and an included angle between the light-incident surface and the plane, where the substrate 3 is located, may be set according to an effective angle of light emitted by the point light source.

In some embodiments, the effective angle of the light emitted by the point light source determines that a ranges from 50° to 70°, and in this case, an included angle i between the light-incident surface and the plane, where the substrate 3 is located, may be set to be 0° to 50°, and an included angle β between the emergent light and the plane, where the substrate 3 is located, may be set to be 33° to 45°.

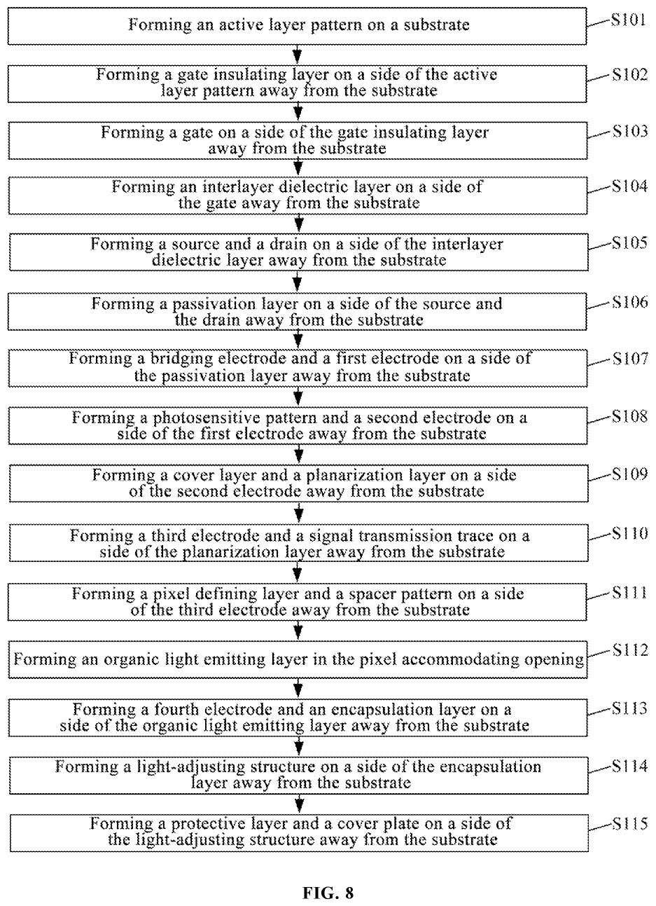

FIG. 5a is a schematic diagram illustrating a structure of a light-adjusting structure according to an embodiment of the present disclosure, and FIG. 5b is a schematic cross-sectional view along a direction A-A′ of FIG. 5a. As shown in FIGS. 5a and 5b, as another alternative embodiment, the light-adjusting structure 4 is in a plano-convex lens shape, and a planar surface of the light-adjusting structure 4 in the plano-convex lens shape faces the substrate 3.

It should be noted that the light-adjusting structure 4 shown in each of FIGS. 4a and 5a of the present disclosure only serves as an example, and does not limit the technical solution of the present disclosure. FIG. 2 shows, by way of example only, the case where the light-adjusting structure 4 has a triangular prism shape.

With continued reference to FIG. 2, in some embodiments, the display panel further includes: an encapsulation layer 5 and a protective layer 6, the encapsulation layer 5 is located on a side of the photosensitive element 2 away from the substrate 3, and the protective layer 6 is located on a side of the encapsulation layer 5 away from the substrate 3. The light-adjusting structure 4 is located between the protective layer 6 and the encapsulation layer 5.

In some embodiments, the encapsulation layer 5 may be a single-layer structure or a multi-layer laminated structure. In practical applications, a film structure of the encapsulation layer 5 may be designed according to practical requirements. Alternatively, the encapsulation layer 5 includes organic encapsulation films 502 and inorganic encapsulation films 501, 503, which are alternately arranged.

The case of two inorganic encapsulation films 501, 503 and one organic encapsulation film 502 is illustrated in FIG. 2 by way of example only. In this case, the film layer in contact with the light-incident surface of the light-adjusting structure 4 is the protective layer 6, the film layer in contact with the light-incident surface of the light-adjusting structure 4 is the inorganic encapsulation film 503, and the refractive index of the light-adjusting structure 4 is greater than the refractive index of the protective layer 6 and less than the refractive index of the inorganic encapsulation film 503. In some embodiments, a material of the protective layer 6 includes an Optically Clear adhesive (OC Adhesive), a material of the inorganic encapsulation film includes silicon nitride (chemical formula of SiNx), the refractive index of the OC Adhesive is about 1.5, and the refractive index of SiNx is about 2.0, so that the light-adjusting structure 4 may be formed with a material having a refractive index of 1.5 to 2.0. For example, the light-adjusting structure 4 may adopt a resin material with a refractive index of 1.5 to 2.0.

With continued reference to FIG. 2, in some embodiments, the photosensitive element 2 includes: a first electrode 201, a photosensitive pattern 202 located on a side of the first electrode 201 away from the substrate 3, and a second electrode 203 located on a side of the photosensitive pattern 202 away from the substrate 3. The photosensitive pattern 202 includes a first semiconductor pattern 202a, a second semiconductor pattern 202c, and an intrinsic pattern 202b, wherein one of the first semiconductor pattern 202a and the second semiconductor pattern 202c is made of a P-type semiconductor material (e.g., P-type amorphous silicon) and the other is made of an N-type semiconductor material (e.g., N-type amorphous silicon).

The display panel further includes: a cover layer 7 and a signal transmission trace 8. The cover layer 7 is located on a side of the photosensitive element 2 away from the substrate 3, and the cover layer 7 has an insulation function. The signal transmission trace 8 is located on a side of the cover layer 7 away from the substrate 3, and is connected to the second electrode 203 in the photosensitive element 2 through a via.

In some embodiments, the signal transmission trace 8 includes a first portion 801 located inside an area where the photosensitive element 2 is located and a second portion 802 located outside the area where the photosensitive element 2 is located. The first portion 801 is connected to the second electrode 203 through the via, and includes a first transparent conductive pattern 801a. The second portion 802 includes: a second transparent conductive pattern 802a, a first metal conductive pattern 802b, and a third transparent conductive pattern 802c, which are stacked in a direction away from the substrate 3, and the second transparent conductive pattern 802a and the first transparent conductive pattern 801a are disposed in a same layer and connected to each other.

In the embodiment of the present disclosure, the first portion 801 is transparent, so that more light may be incident on the photosensitive element 2. The second portion 802 is a laminated structure of a plurality of conductive film layers, so that an overall equivalent resistance of the second portion 802 is reduced to improve the quality of signal transmission.

In some embodiments, the display panel further includes a pixel defining layer 9. The pixel defining layer 9 is located on a side of the photosensitive element 2 away from the substrate 3, and has a plurality of pixel accommodating openings, which correspond to the plurality of display elements 10 in a one-to-one correspondence. The display elements 10 each are located in a corresponding pixel accommodating opening, and there is no overlap between an orthographic projection of the display elements 10 on the substrate 3 and an orthographic projection of the photosensitive elements 2 on the substrate 3.

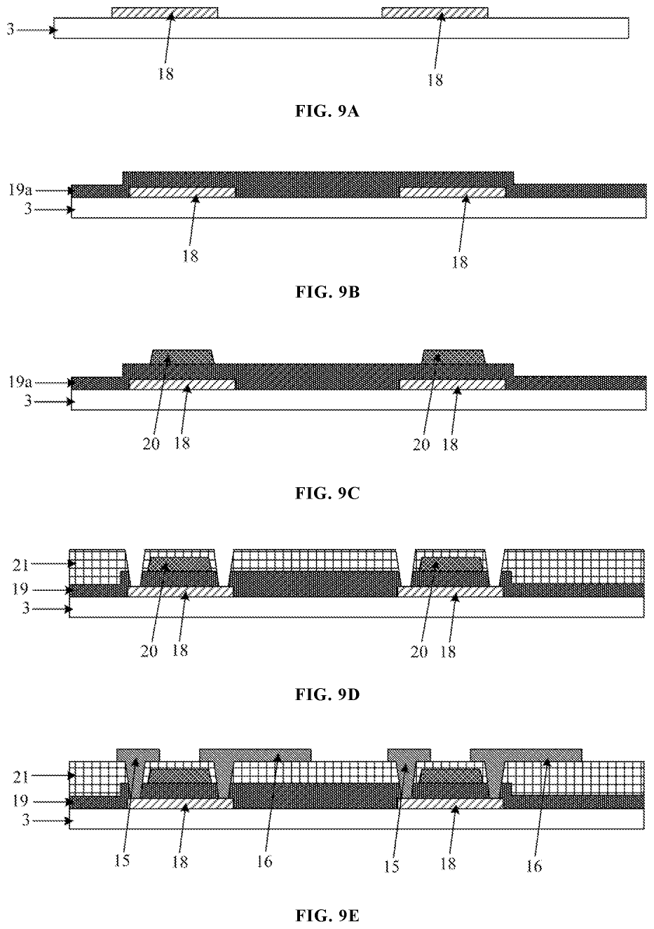

FIG. 6 is a schematic diagram illustrating how to arrange display elements and photosensitive elements according to an embodiment of the present disclosure. As shown in FIG. 6, the photosensitive element 2 may be disposed in a spacing region between two adjacent display elements 10; the orthographic projections of the photosensitive element 2 and the display elements 10 on the substrate 3 do not overlap with each other, so that it can be ensured that the arrangement of the photosensitive elements 2 will not affect the normal display of the display elements 10.

In some embodiments, the orthographic projection of the light-adjusting structure 4 on the substrate 3 is within the area defined by the orthographic projection of a corresponding photosensitive element 2 on the substrate 3. Further, the orthographic projection of the light-adjusting structure 4 on the substrate 3 is completely overlapped with the area defined by the orthographic projection of the corresponding photosensitive element 2 on the substrate 3.

In practical applications, the larger the overall size of the light-adjusting structure 4 is, the larger the size of the light-incident surface of the light-adjusting structure 4 is, the more the received incident light is, and the more the emergent light output to the corresponding photosensitive element 2 is, which is facilitated to print recognition. However, if the size of the light-adjusting structure is too large, the light-adjusting structure may cover the area where the display element 10 is located, thereby decreasing the aperture ratio of the pixel and affecting the display quality. For this reason, according to an embodiment of the present disclosure, the light-adjusting structure 4 is disposed in the area where the corresponding photosensitive element 2 is located. Preferably, the orthographic projection of the light-adjusting structure 4 on the substrate 3 is completely overlapped with the area defined by the orthographic projection of the corresponding light sensing element 2 on the substrate 3, and in this case, the normal display of the display elements 10 is not affected under the condition of ensuring that the emergent light output to the corresponding light sensing element 2 is as much as possible.

In some embodiments, a material of the pixel defining layer 9 includes a color filter material, having a light transmission wavelength in a range of 380 nm-600 nm and an absorption wavelength greater than 600 nm. That is, the color filter material allows visible light to pass through but prevents light having a wavelength greater than 600 nm from passing through. Thus, the light with the wavelength greater than 600 nm in the ambient light can be prevented from penetrating through the finger and incident on the photosensitive element 2 to generate noise. In other words, by providing the pixel defining layer 9 with the color filter material, the signal-to-noise ratio of the photosensitive element 2 can be increased, thereby improving definition of fingerprint imaging.

In some embodiments, the display panel further includes a planarization layer 11, the planarization layer 11 is located between the photosensitive elements 2 and the pixel defining layer 9. By arranging the planarization layer 11, a planarized surface may be provided before the display element 10 is formed, so that the quality of films of the display element 10 formed in subsequent processes can be improved, which is facilitated to improvement of the yield of products.

In some embodiments, the display panel further includes a thin film transistor array, which is located on a side of the photosensitive elements 2 facing the substrate 3. The thin film transistor array includes a plurality of thin film transistors 14, each thin film transistor 14 corresponds to one photosensitive element 2 or one display element 10, and the thin film transistor 14 is electrically connected to a corresponding photosensitive element 2 or a corresponding display element 10.

In some embodiments, a passivation layer 17 is disposed on a side of the thin film transistor array away from the substrate 3, and the first electrode 201 of the photosensitive element 2 is connected to a corresponding thin film transistor 14 (specifically, a source 15 or a drain 16 of the thin film transistor 14) through a via in the passivation layer 17.

The display element 10 includes a third electrode 1001, a fourth electrode 1003, and an organic light emitting layer 1002 between the third electrode 1001 and the fourth electrode 1003. The display panel further includes a bridging electrode 12 disposed in a same layer as the first electrode 201, the bridging electrode 12 is connected to a corresponding thin film transistor 14 (the source 15 or the drain 16 of the thin film transistor 14) through a via in the passivation layer 17, and the third electrode 1001 is connected to the bridging electrode 12 through a via in the planarization layer 11 and the cover layer 7, so that the third electrode 1001 is electrically connected to the corresponding thin film transistor 14.

Alternatively, in some embodiments, the passivation layer 17 and the bridging electrode 12 may not be provided, and the third electrode 1001 is connected to the corresponding thin film transistor 14 through a via in the planarization layer 11 and the cover layer 7, and the first electrode 201 is disposed in a same layer as the source 15/drain 16 of the thin film transistor 14 and is directly connected to the source 15 or the drain 16. No corresponding drawings are provided in this case.

An embodiment of the present disclosure further provides a display apparatus, where the display apparatus includes a display panel, and the display panel adopts the display panel provided in the foregoing embodiment, and specific contents may refer to the description in the foregoing embodiment, and are not repeated here.

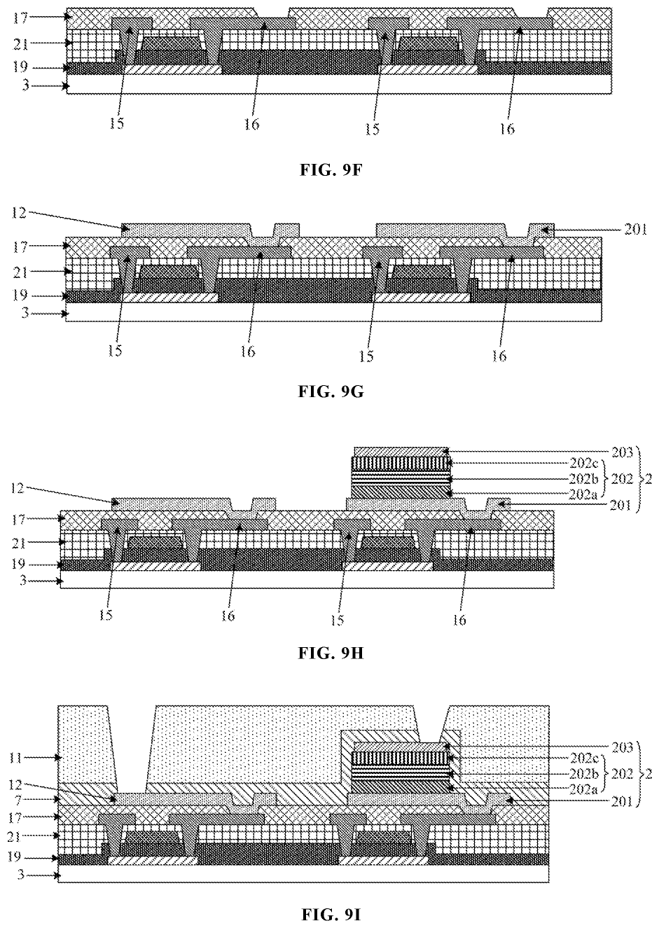

FIG. 7 is a flowchart of a method for manufacturing a display panel according to an embodiment of the present disclosure. As shown in FIG. 7, the method is used to manufacture the display panel according to the above embodiment, and includes:

Step Sa, forming a plurality of photosensitive elements on a substrate; and

Step Sb, forming a light-adjusting structure on a side of the photosensitive elements away from the substrate.

For specific descriptions of the photosensitive element and the light-adjusting structure, reference may be made to corresponding contents in the foregoing embodiments, and details are not repeated here.

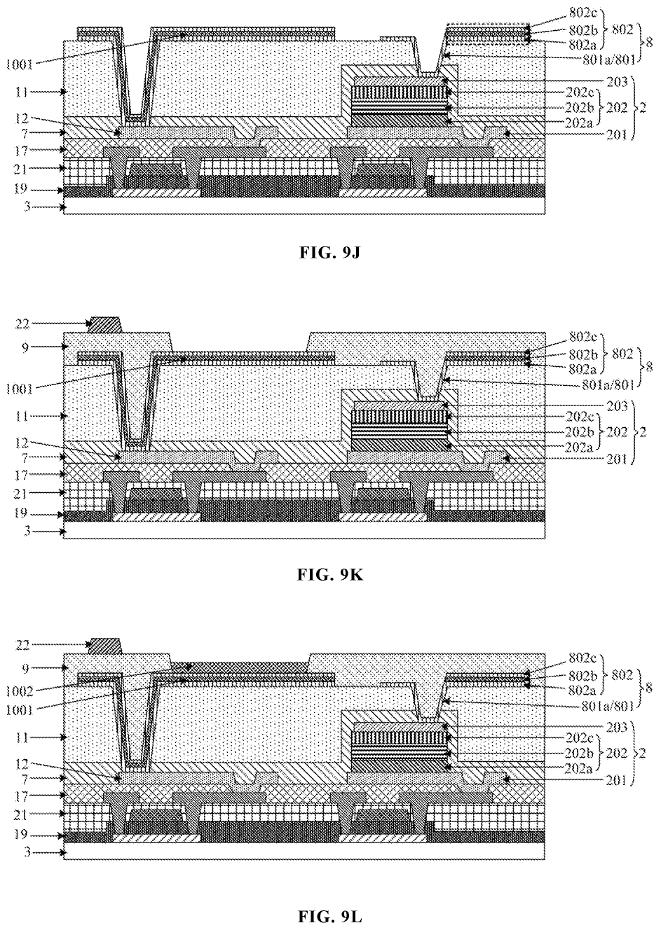

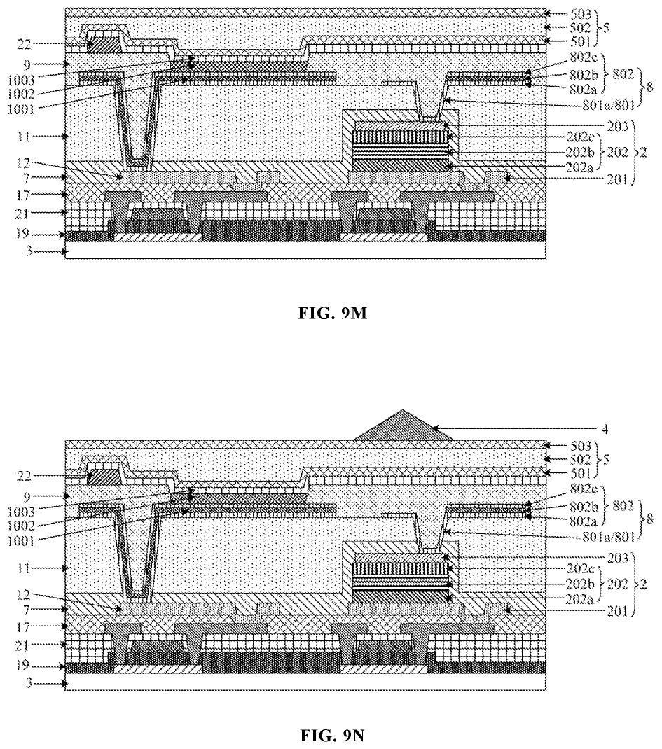

FIG. 8 is a flowchart of a method for manufacturing a display panel according to an embodiment of the present disclosure, and FIGS. 9A to 9N are schematic cross-sectional views of intermediate products for manufacturing a display panel with the manufacturing method shown in FIG. 8. As shown in FIGS. 8 to 9N, the manufacturing method may be used for manufacturing the display panel shown in FIG. 2, and the manufacturing method includes:

Step S101, forming an active layer pattern on a substrate.

Referring to FIG. 9A, an active material film is first deposited on the substrate 3, and then a patterning process (Photo process) is performed on the active material thin film to obtain an active layer pattern 18. The material of the active material film may include a semiconductor material such as amorphous silicon and metal oxide.

The patterning process according to the embodiment of the present disclosure is generally referred to as a process including photoresist coating, exposure, development, thin film etching, photoresist stripping, and the like. When the material of the film to be patterned is a photoresist material, the patterning of the photoresist material film may be realized only through the steps of exposure and development.

S102, forming a gate insulating layer on a side of the active layer pattern away from the substrate.

Referring to FIG. 9B, a gate insulating material film 19a is deposited on the side of the active layer pattern 18 away from the substrate 3. The gate insulating material film 19a may be a silicon oxide film, a silicon nitride film, or a laminated structure of a silicon oxide film and a silicon nitride film.

Step S103, forming a gate on a side of the gate insulating layer away from the substrate.

Referring to FIG. 9C, a gate material film is first deposited on a side of the gate insulating layer 19a away from the substrate 3, and then a patterning process is performed on the gate material film to obtain a pattern of the gate 20. A material of the gate material film may be a metal material, such as molybdenum, titanium, aluminum, and the like.

Step S104, forming an interlayer dielectric layer on a side of the gate away from the substrate.

Referring to FIG. 9D, an interlayer dielectric material film is first deposited on the side of the gate 20 away from the substrate 3, and then the interlayer dielectric material film and the insulating material film are patterned together to form a via communicated to the active layer pattern 18, thereby obtaining patterns of the gate insulating layer 19 and the interlayer dielectric layer 21. The interlayer dielectric material film may be a silicon oxide film, a silicon nitride film or a laminated structure formed by a silicon oxide film and a silicon nitride film.

Step S105, forming a source and a drain on a side of the interlayer dielectric layer away from the substrate.

Referring to FIG. 9E, a source/drain material film is first deposited on a side of the interlayer dielectric layer 21 away from the substrate 3, and then the source/drain material film is patterned to obtain patterns of the source 15 and the drain 16. The source 15 and the drain 16 are connected to the active layer pattern 18 through corresponding vias, respectively. The source/drain material film may be made of a metal material such as molybdenum, titanium, aluminum and the like; the source/drain material film may be a single-layer film structure or a multi-layer film laminated structure.

Step S106, forming a passivation layer on a side of the source and the drain away from the substrate.

Referring to FIG. 9F, a passivation material film is first deposited on a side of the source 15 and the drain 16 away from the substrate 3, and then a patterning process is performed on the passivation material film to form a via communicated to the source 15 or the drain 16. The figure illustrates a case where the via in the passivation layer 17 is communicated to the drain 16. The passivation material film may be a silicon oxide film, a silicon nitride film, or a laminated structure of a silicon oxide film and a silicon nitride film.

S107, forming a bridging electrode and a first electrode on a side of the passivation layer away from the substrate.

Referring to FIG. 9G, a first electrode material film is first deposited on a side of the passivation layer 17 away from the substrate 3, and then the first electrode material film is patterned to obtain patterns of the bridging electrode 12 and the first electrode 201. The bridging electrode 12 and the first electrode 201 are connected to the corresponding drains 16 through vias, respectively. The material of the first electrode material film may be a metal material, such as molybdenum, titanium, aluminum, or the like. The first electrode material film may have a single-layer film structure or a multi-layer film laminated structure.

Step S108, forming a photosensitive pattern and a second electrode on a side of the first electrode away from the substrate.

Referring to FIG. 9H, firstly, a photosensitive material film and a second electrode material film are sequentially deposited on a side of the first electrode away from the substrate 3, then the second electrode material film is patterned to obtain an initial pattern of the second electrode 203, then the photosensitive material film is patterned by using the initial pattern of the second electrode 203 as a mask to obtain a photosensitive pattern 202, then the initial pattern of the second electrode 203 is patterned to obtain a final pattern of the second electrode 203, and an orthographic projection of the photosensitive pattern 202 on the substrate 3 completely covers an orthographic projection of the final pattern of the second electrode 203 on the substrate 3. The photosensitive material film includes an N-type semiconductor material film (e.g., an N-type amorphous silicon film), an intrinsic material film (e.g., an amorphous silicon film), and a P-type semiconductor material film (e.g., a P-type amorphous silicon film), which are stacked in a direction away from the substrate 3. The second electrode material film includes a transparent conductive material film (ensuring that light can enter the photosensitive pattern), such as an indium tin oxide material film. In this case, the photosensitive pattern 202 includes a first semiconductor pattern 202a, a second semiconductor pattern 202c, and an intrinsic pattern 202b.

When the initial pattern of the second electrode 203 is used as a mask to pattern the photosensitive material film, a certain amount of lateral etching exists during the etching process, so that the size of the initial pattern of the second electrode 203 is slightly greater than the size of the photosensitive pattern 202, and in this case, an unstable current is generated on the surface of the photosensitive pattern 202, which causes a large noise in an electrical signal output by the photosensitive element 2, and therefore, after the patterning of the photosensitive pattern 202 is completed, a second patterning process needs to be performed on the second electrode 203, so that the size of the second electrode 203 is reduced.

Step S109, forming a cover layer and a planarization layer on a side of the second electrode away from the substrate.

Referring to FIG. 9I, a cover material film is first deposited on a side of the second electrode away from the substrate 3, a planarization material film is then coated on a side of the cover material film, then the planarization material film is patterned to form a via communicated to the cover material film, so as to obtain the pattern of the planarization layer 11, and then the planarization layer 11 is used as a mask to pattern the cover material film, so as to form vias communicated to the second electrode 203 and the bridging electrode 12, respectively, so as to obtain the pattern of the cover layer 7. The planarization material film is a resin material film, and the cover material film may be a silicon oxide film, a silicon nitride film or a laminated structure composed of a silicon oxide film and a silicon nitride film.

Step S110, forming a third electrode and a signal transmission trace on a side of the planarization layer away from the substrate.

Referring to FIG. 9J, first, a first transparent conductive material film, a metal conductive material film and a second transparent conductive material film are sequentially deposited on a side of the cover layer 7 away from the substrate 3. Then, a patterning process is performed on the first transparent conductive material film, the metal conductive material film and the second transparent conductive material film to obtain a pattern of the third electrode 1001 and an initial pattern of the signal transmission trace 8. The initial pattern of the transmission trace 8 includes a first portion 801 located in the area where the photosensitive element 2 is located and a second portion 802 located outside the area where the photosensitive element 2 is located. The first portion 801 at this time includes a first transparent conductive pattern 801a, a second metal conductive pattern (not shown), and a fourth transparent conductive pattern (not shown), which are stacked in a direction away from the substrate 3. The second portion 802 includes a second transparent conductive pattern 802a, a first metal conductive pattern 802b, and a third transparent conductive pattern 802c, which are stacked in a direction away from the substrate 3. And then, the fourth transparent conductive pattern and the second metal conductive pattern are sequentially removed through two etching processes, to obtain a final pattern of the signal transmission trace 8.

In some embodiments, the first transparent conductive material film and the second transparent conductive material film are both indium tin oxide films, and the metal conductive material film is a silver film.

It should be noted that, the case where the second portion 802 of the signal transmission trace 8 and the third electrode 1001 adopt a three-layer laminated structure of conductive films is only a preferred embodiment of the present disclosure, which can reduce the overall resistances of the second portion 802 of the signal transmission trace 8 and the third electrode 1001, and is beneficial to signal transmission.

In addition, in order to ensure that the first portion 801 including only the first transparent conductive pattern can normally transmit signals, it is necessary to make the first transparent conductive pattern 801a have a certain thickness, to reduce the overall resistance of the first portion 801, so that the first portion 801 can normally transmit signals (the first portion is generally used to provide a negative bias). In some embodiments, the thickness of first transparent conductive pattern 801a is greater than or equal to 400 angstrom.

Step S111, forming a pixel defining layer and a spacer pattern on a side of the third electrode away from the substrate.

Referring to FIG. 9K, a color filter material film is first formed on a side of the third electrode away from the substrate 3, and then the color filter material film is patterned to form a pixel accommodating opening, which is communicated to the third electrode. Then, a spacer material film is formed on a side of the pixel defining layer 9 away from the substrate 3, and patterned to obtain a spacer pattern 22. The spacer pattern 22 is disposed between adjacent pixel accommodating openings to prevent a color mixing problem caused by depositing organic light emitting layers in the pixel accommodating openings through evaporation processes.

The color filter material film has a light transmission wavelength in a range of 380 nm to 600 nm, and an absorption wavelength greater than 600 nm.

Step S112, forming an organic light emitting layer in the pixel accommodating opening.

Referring to FIG. 9L, a corresponding organic light emitting layer 1002 is formed in each pixel accommodating opening by an evaporation process.

Step S113, forming a fourth electrode and an encapsulation layer on a side of the organic light emitting layer away from the substrate.

Referring to FIG. 9M, a transparent conductive material film is deposited on aside of the organic light emitting layer 1002 away from the substrate, 3 to obtain a fourth electrode 1003. An encapsulation material film is deposited on a side of the fourth electrode 1003 away from the substrate 3, so as to obtain an encapsulation layer 5. The encapsulation material film includes an organic encapsulation film 502 (e.g., a resin material film) and inorganic encapsulation films 501 and 503 (e.g., a silicon oxide film, a silicon nitride film, or a laminated structure of a silicon oxide film and a silicon nitride film), which are alternately arranged. The figure illustrates a case of two inorganic encapsulation films 501, 503 and one organic encapsulation film 502.

Step S114, forming a light-adjusting structure on a side of the encapsulation layer away from the substrate.

Referring to FIG. 9N, in some embodiments, the light-adjusting structure 4 has a triangular prism shape, and the step of forming the light-adjusting structure 4 includes: firstly, forming a preset photoresist material film on a side of the photosensitive element 2 away from the substrate 3, and performing a patterning process on the photoresist material film so as to obtain an initial pattern of the light-adjusting structure 4 in an area where the light-adjusting structure 4 is to be formed; then, performing a patterning process on the initial pattern of the light-adjusting structure 4 for multiple times, so that the initial pattern of the light-adjusting structure 4 has a step morphology on a surface away from the substrate 3; and then, performing a baking process on the initial pattern of the light-adjusting structure 4, so that the photoresist material forming the step morphology is heated, melted and flows to form an inclined surface, thereby obtaining a final pattern of the light-adjusting structure 4.

In some embodiments, the light-adjusting structure 4 has a plano-convex lens shape, and the step of forming the light-adjusting structure 4 includes: firstly, forming a preset photoresist material film on a side of the photosensitive element 2 away from the substrate 3, and performing a patterning process on the photoresist material film so as to obtain an initial pattern of the light-adjusting structure 4 in an area where the light-adjusting structure 4 is to be formed; and then, performing a baking process on the initial pattern of the light-adjusting structure 4, so that the photoresist material on an outer surface of the initial pattern of the light-adjusting structure 4 is heated, melted, and flows to form a curved surface, thereby obtaining a final pattern of the light-adjusting structure 4.

In some embodiments, the refractive index of the light-adjusting structure 4 is greater than the refractive index of the protective layer 6 to be formed subsequently and less than the refractive index of the inorganic encapsulation film 503.

Step S115, forming a protective layer and a cover plate on a side of the light-adjusting structure away from the substrate.

Referring to FIG. 2, firstly, an OC adhesive is coated on a side of the light-adjusting structure 4 away from the substrate 3, to obtain a protective layer 6. A surface of the protective layer 6 away from the substrate 3 is a plane. Then, the cover plate 1 is disposed on a side of the protective layer 6 away from the substrate 3, to obtain the display panel shown in FIG. 2.

It will be understood that the above embodiments are merely exemplary embodiments adopted to illustrate the principles of the present disclosure, and the present disclosure is not limited thereto. It will be apparent to one of ordinary skill in the art that various changes and modifications can be made without departing from the spirit and scope of the present disclosure, and these changes and modifications are to be considered within the scope of the present disclosure.

1. A display panel, comprising a substrate and a plurality of photosensitive elements on the substrate, wherein at least a part of the plurality of photosensitive elements each are provided with a light-adjusting structure;
the light-adjusting structure is on a side of the photosensitive element away from the substrate, and is configured to adjust a propagation direction of incident light reflected by a print and incident on the light-adjusting structure, and to output formed emergent light to the photosensitive element corresponding to the light-adjusting structure, and an included angle between a propagation direction of the formed emergent light and a plane, where the substrate is located, is greater than an included angle between the propagation direction of the incident light and the plane where the substrate is located; and
the photosensitive element is configured to generate a corresponding electrical signal according to received light, to identify an image of the print.

2. The display panel according to claim 1, wherein the light-adjusting structure has a light-incident surface and a light-emergent surface, the light-incident surface is on a side of the light-adjusting structure away from the substrate, and the light-emergent surface is on a side of the light-adjusting structure close to the substrate; and
in the display panel, a refractive index of a film layer in contact with the light-incident surface of the light-adjusting structure is less than that of the light-adjusting structure, and a refractive index of a film layer in contact with the light-emergent surface of the light-adjusting structure is greater than that of the light-adjusting structure.

3. The display panel according to claim 1, wherein the light-adjusting structure has a triangular prism shape, and the light-adjusting structure in the triangular prism shape has a triangular cross-sectional shape in a cross section perpendicular to a plane where the substrate is located; or
the light-adjusting structure has a plano-convex lens shape, and a planar surface of the light-adjusting structure in the plano-convex lens shape is close to the substrate.

4. The display panel according to claim 1, wherein an orthographic projection of the light-adjusting structure on the substrate is within an area defined by an orthographic projection of the photosensitive element corresponding to the light-adjusting structure on the substrate.

5. The display panel according to claim 1, further comprising:
an encapsulation layer on a side of the plurality of photosensitive elements away from the substrate; and
a protective layer on a side of the encapsulation layer away from the substrate,
wherein the light-adjusting structure is between the protective layer and the encapsulation layer.

6. The display panel according to claim 1, wherein each of the plurality of photosensitive elements comprises a first electrode, a photosensitive pattern on a side of the first electrode away from the substrate, and a second electrode on a side of the photosensitive pattern away from the substrate; and
the display panel further comprises:
a cover layer on a side of the photosensitive element away from the substrate; and
a signal transmission trace on a side of the cover layer away from the substrate, and connected to the second electrode of the photosensitive element through a via.

7. The display panel according to claim 1, wherein the signal transmission trace comprises a first portion in an area where the photosensitive elements is located, and a second portion outside the area where the photosensitive element is located;
the first portion is connected to the second electrode through a via, and comprises a first transparent conductive pattern; and
the second portion comprises a second transparent conductive pattern, a first metal conductive pattern and a third transparent conductive pattern, which are stacked in a direction away from the substrate, and the second transparent conductive pattern and the first transparent conductive pattern are in a same layer and are connected to each other.

8. The display panel according to claim 1, further comprising a pixel defining layer and a plurality of display elements;
wherein the pixel defining layer is on a side of the plurality of photosensitive elements away from the substrate, and is provided with a plurality of pixel accommodating openings, which correspond to the plurality of display elements in a one-to-one correspondence; and
each of the plurality of display elements is in a corresponding one of the plurality of pixel accommodating openings, and an orthographic projection of the plurality of display elements on the substrate does not overlap an orthographic projection of the plurality of photosensitive elements on the substrate.

9. The display panel according to claim 8, further comprising:
a thin film transistor array on a side of the plurality of photosensitive elements close to the substrate, and comprising a plurality of thin film transistors,
wherein each of the plurality of thin film transistors corresponds to and electrically connected to one of plurality of photosensitive elements or one of the plurality of display elements.

10. The display panel according to claim 8, wherein a material of the pixel defining layer comprises a color filter material having a transmission wavelength ranging from 380 nm to 600 nm and an absorption wavelength greater than 600 nm.

11. The display panel according to claim 8, further comprising:
a planarization layer between the plurality of photosensitive elements and the pixel defining layer.

12. A display apparatus, comprising the display panel according to claim 1.

13. The display apparatus according to claim 12, wherein the light-adjusting structure has a light-incident surface and a light-emergent surface, the light-incident surface is on a side of the light-adjusting structure away from the substrate, and the light-emergent surface is on a side of the light-adjusting structure close to the substrate; and
in the display panel, a refractive index of a film layer in contact with the light-incident surface of the light-adjusting structure is less than that of the light-adjusting structure, and a refractive index of a film layer in contact with the light-emergent surface of the light-adjusting structure is greater than that of the light-adjusting structure.

14. The display apparatus according to claim 12, wherein the light-adjusting structure has a triangular prism shape, and the light-adjusting structure in the triangular prism shape has a triangular cross-sectional shape in a cross section perpendicular to a plane where the substrate is located; or
the light-adjusting structure has a plano-convex lens shape, and a planar surface of the light-adjusting structure in the plano-convex lens shape is close to the substrate.

15. The display apparatus according to claim 12, wherein an orthographic projection of the light-adjusting structure on the substrate is within an area defined by an orthographic projection of the photosensitive element corresponding to the light-adjusting structure on the substrate.

16. The display apparatus according to claim 12, wherein the display panel further comprises:
an encapsulation layer on a side of the plurality of photosensitive elements away from the substrate; and
a protective layer on a side of the encapsulation layer away from the substrate,
wherein the light-adjusting structure is between the protective layer and the encapsulation layer.

17. The display apparatus according to claim 12, wherein each of the plurality of photosensitive elements comprises a first electrode, a photosensitive pattern on a side of the first electrode away from the substrate, and a second electrode on a side of the photosensitive pattern away from the substrate; and
the display panel further comprises:
a cover layer on a side of the photosensitive element away from the substrate; and
a signal transmission trace on a side of the cover layer away from the substrate, and connected to the second electrode of the photosensitive element through a via.

18. The display apparatus according to claim 12, wherein the signal transmission trace comprises a first portion in an area where the photosensitive elements is located, and a second portion outside the area where the photosensitive element is located;
the first portion is connected to the second electrode through a via, and comprises a first transparent conductive pattern; and
the second portion comprises a second transparent conductive pattern, a first metal conductive pattern and a third transparent conductive pattern, which are stacked in a direction away from the substrate, and the second transparent conductive pattern and the first transparent conductive pattern are in a same layer and are connected to each other.

19. The display apparatus according to claim 12, wherein the display panel further comprises a pixel defining layer and a plurality of display elements;
wherein the pixel defining layer is on a side of the plurality of photosensitive elements away from the substrate, and is provided with a plurality of pixel accommodating openings, which correspond to the plurality of display elements in a one-to-one correspondence; and
each of the plurality of display elements is in a corresponding one of the plurality of pixel accommodating openings, and an orthographic projection of the plurality of display elements on the substrate does not overlap an orthographic projection of the plurality of photosensitive elements on the substrate.

20. The display apparatus according to claim 19, wherein the display panel further comprises:
a thin film transistor array on a side of the plurality of photosensitive elements close to the substrate, and comprising a plurality of thin film transistors,
wherein each of the plurality of thin film transistors corresponds to and electrically connected to one of plurality of photosensitive elements or one of the plurality of display elements.
